(19) United States
(12) Patent Application Publication
(10) Pub. No.: US 2018/0083592 A1
(43) Pub. Date: Mar. 22, 2018

(54) ELECTROACOUSTIC COMPONENT WITH IMPROVED ACOUSTICS

(71) Applicant: SNAPTRACK, INC., San Diego, CA (US)

(72) Inventors: Stephan BOLZE, München (DE); Christian MATH, München (DE)

(21) Appl. No.: 15/565,259

(22) PCT Filed: Jan. 28, 2016
(86) PCT No.: PCT/EP2016/051810

§ 371 Date: Oct. 9, 2017

(30) Foreign Application Priority Data
Apr. 22, 2015 (DE) 10 2015 106 191.0

(51) Int. Cl. H03H 9/02; H03H 9/145; H03H 9/64; H03H 3/08; H01L 41/08; H01L 41/187; H01L 41/29; H01L 41/338

(52) U.S. Cl. CPC H03H 9/02842; H03H 9/145; H03H 9/6489; H01L 41/338; H01L 41/081; H01L 41/1873; H01L 41/29; H03H 3/08

(57) ABSTRACT

An electro-acoustic component with improved acoustics is specified. The component comprises a rectangular chip whose side edges are rotated relative to the piezoelectric axis.

The invention relates to electro-acoustic components with improved acoustics, particularly with reduced interference due to acoustic waves reflected at substrate edges. The invention further relates to HF filters which are implemented by means of such components, wafers for the production of such components, and methods for the production thereof.

In electro-acoustic components, transducer structures switch between HF structures and acoustic waves (AW). The transducer structures comprise electrode structures, e.g. electrode fingers, and in doing so are connected to a piezoelectric material, e.g. a piezoelectric wafer.

The AWs propagate in components operating with surface acoustic waves (SAWs), preferably on the surface of the piezoelectric material. Waves that exit the transducer structures, are reflected at an edge or surface of the piezoelectric material, and meet again on the transducer structures with an incorrect phase position are problematic.

Normally, components working with AWs are used as bandpass filters or bandstop filters. The transducer structures and reflector elements then have a spatial periodicity which is determined essentially by the acoustic wavelength λ or λ/2 corresponding to the bandpass frequency. Particularly problematic are AWs whose corresponding frequency is slightly higher than the bandpass frequency, because such waves can relatively easily overcome reflector elements.

In order to reduce the disadvantageous effects of reflected waves, the backside surface of SAW chips can be roughened in order to scatter the AWs. However, this increases the fracture rate of the corresponding substrates.

Furthermore, the substrate edges can be enclosed by an AW-absorbing compound.

In addition, it is possible to use chips having a non-rectangular footprint.

A further option exists in tilting the electrode fingers such that they no longer have a rectangular footprint together with the—unmodified—busbars.

Each of these approaches for reducing the interference caused by reflected AWs has disadvantages, however, for example in producing the component itself or with its enclosure.

Therefore, there is the desire to provide electro-acoustic components whose acoustics are improved in a different, more beneficial manner.

To this end, the independent claims specify improved components, improved wafers, improved production methods, and improved HF filters. Dependent claims specify corresponding advantageous embodiments.

An electro-acoustic component comprises a carrier chip with a piezoelectric material having a piezoelectric axis. The component further comprises AW transducer structures having electrode fingers which are arranged on the carrier chip. The AW transducer structures in this case are suitable and intended to switch between acoustic waves (AW) and HF signals for this purpose. The electrode fingers are oriented at a right angle with respect to the piezoelectric axis. The piezoelectric axis does not intersect any of the substrate edges at a right angle.

Right angles are disadvantageous if reflections are supposed to be reduced. However, right angles are advantageous when producing electro-acoustic components, because edges that are not oriented at a right angle require an increased effort to produce.

The described component has an optimal excitation strength and optimal electro-acoustic coupling due to the right-angled arrangement of the electrode fingers with respect to the piezoelectric axis. Due to a possible rectangular cross-section of the carrier chip, simple processing during the production of the component is enabled by means of the rectangular cutting edges during separation.

However, chips with edges that are not necessarily straight are also possible. Irregularly structured edges help to prevent coherent reflections, such that scattering of undesirable signals is obtained.

Due to the fact that the piezoelectric axis is not oriented at a right angle or parallel to the substrate edges of the rectangular carrier substrate, the interference due to reflected AWs is improved, and thus an improved electro-acoustic component is obtained.

Thus, an electro-acoustic component is provided in which the electrode fingers are tilted relative to the substrate edges. However, this also entails an increased need for surface area, because the component structures, e.g. electro-acoustic transducer structures, generally formed at a right angle and the rectangular carrier chip are rotated relative to one another, and the component structures can no longer optimally fill out the chip. Areas that cannot be used by the electrode fingers result at the edges of the carrier chip because—contrary to known methods in which only the electrode fingers are tilted—the busbars are also rotated relative to the substrate edges.

Such a component has improved electro-acoustic properties, particularly at frequencies just above a passband frequency. Thus, there are embodiments in which the insertion loss is improved by 4.5 dB.

At the same time, neither acoustic nor electric properties are worsened—as shown by model calculations and actual constructed test setups.

It is possible for the carrier chip to have a rectangular cross-section. Rectangular components are often preferably requested.

Given bare die packages or WLPs (Wafer Level Packages), for example, non-rectangular substrates are practically incompatible without a very extensive modification effort.

It is also possible for the carrier chip to have an essentially rectangular cross-section and for the edges to be structured. The edges may be structured such that the edges are not oriented vertically with respect to the piezo axis, at least in areas intended for this.

It is possible for the piezoelectric axis and a substrate edge to enclose an angle which is within an interval of [80°, . . . , 87°]. In other words: the transducer structures may be rotated by an angle between, and including, 3° (90°−87°) and 10° (90°−80°). The reduction of the interfering effects of the reflected AWs is then already relatively high, while the additional surface area required still remains relatively low.

Other angles of rotation, e.g. between 1° and 30°, e.g. between 5° and 20°, are likewise possible.

It is possible for the piezoelectric material to be a piezoelectric monocrystal.

The electrode fingers may be used to generate SAWs or GBAWs (GBAW=Guided Bulk Acoustic Wave).

The electrode fingers and further elements of the transducer structures can then be arranged directly on the crystalline piezoelectric material. The propagation direction of the AWs is thereby preferably oriented parallel to the piezoelectric axis, whereby a good electro-acoustic coupling is obtained.

The piezoelectric material may be LiTaO₃ (lithium tantalate) or LiNbO₃ (lithium niobate). The customary crystal sections for lithium tantalate or lithium niobate can be used.

It is possible for the transducer structures to have two busbars which are oriented at a right angle with respect to the electrode fingers.

It is furthermore possible for the transducer structures to comprise DMS structures (DMS=Dual Mode SAW).

As an alternative or in addition to this, the transducer structures may comprise ladder-type structures. Ladder-type structures are thereby constructed from basic elements with a parallel resonator and a serial resonator.

DMS structures generally react particularly sensitively to reflected AWs. Ladder-type structures are relatively output-stable. A combination of ladder-type structures with DMS structures thus results in an especially output-stable HF filter which benefits especially significantly from the reduction in the interference of acoustic waves.

It is therefore particularly possible for the electro-acoustic component to implement an HF filter circuit or part of an HF filter circuit. An HF filter which has corresponding component structures may thereby itself be part of an electro-acoustically functioning duplexer.

Customary wafers on which transducer structures for electro-acoustic components are arranged comprise lateral markings, particularly edges with a straight-line progression. Such edges are characterized as “primary flat” or as “secondary flat”. The markings served to indicate the orientation of the wafer, of the crystalline axes of the wafer material, and of the component structures arranged thereupon. Customary process steps for producing electro-acoustic components are therefore coordinated with the orientation of the markings. Normally, a plurality of electro-acoustic components is structured for multiple uses. The individual components are subsequently separated. Further structures, e.g. contact structures for connecting to external circuitry environments, are attached to the piezo-electric material. Both the process steps for separating as well as the process steps for applying further structures require precisely oriented wafers. If the edges of the subsequent individual chips and circuitry structures for external circuitry environments are then rotated relative to the piezo-electric axis whose orientation is indicated by the marking of the wafer, a complex adaptation of the processing steps will then be required. It is therefore possible to provide a wafer comprising a piezoelectric material with a piezoelectric axis and having a first marking. The first marking, e.g. the “primary flat”, is provided in order to indicate the orientation of the wafer. The marking comprises an edge section progressing in a straight line. Compared to customary wafers which require complex modifications in the processing steps, the piezoelectric axis intersects the edge section of the marking at an angle that deviates from a right angle.

The deviation from a right angle in this case may correspond to the angle at which the component structures, particularly the electrode fingers, are rotated relative to the substrate edges. This means that the subsequent cut edges and connection elements for external connections will be oriented according to the marking, in conformance with customary processing steps. The problem of rotation is thereby shifted to the placement of a quasi-rotated marking, which is simpler to execute.

It is possible for the deviation |α3−90| from the right angle to be in an interval between 3° and 10°, wherein the interval limits themselves may also indicate potential angle deviations. Moreover, the angles of rotation indicated above for the component may be used.

A method for producing an electro-acoustic component or a plurality of electro-acoustic components may comprise the following steps:
Provision of a wafer in which the marking is not at a right angle to the piezoelectric axis, e.g. is rotated by an angle between 3° and 10°;
Formation of the transducer structures of the components on the wafer;
Separation of the components by separating the wafer into chips in which the edges are oriented parallel or at a right angle to the marking of the wafer.

This means that the use of a wafer with specially applied marking simplifies production. However, typical wafers may also be used in order to obtain improved components. In doing so, however, an adaptation of the process steps to a rotation between the chip edges and the markings is required. A corresponding process comprises the steps:
Provision of a wafer;
Formation of the transducer structures of the components on the wafer;
Separation of the components by separating the wafer into chips.

The separation of the chips thereby can take place by sawing the wafer.

It is also possible for the component structures to be rotated by an angle within an interval [3°, . . . , 10°] relative to the right-angled orientation of the subsequent chip edges.

The component, correspondingly designed wafer, and method for producing components shall be explained in more detail by means of schematic and non-limiting Figures. The following is shown:

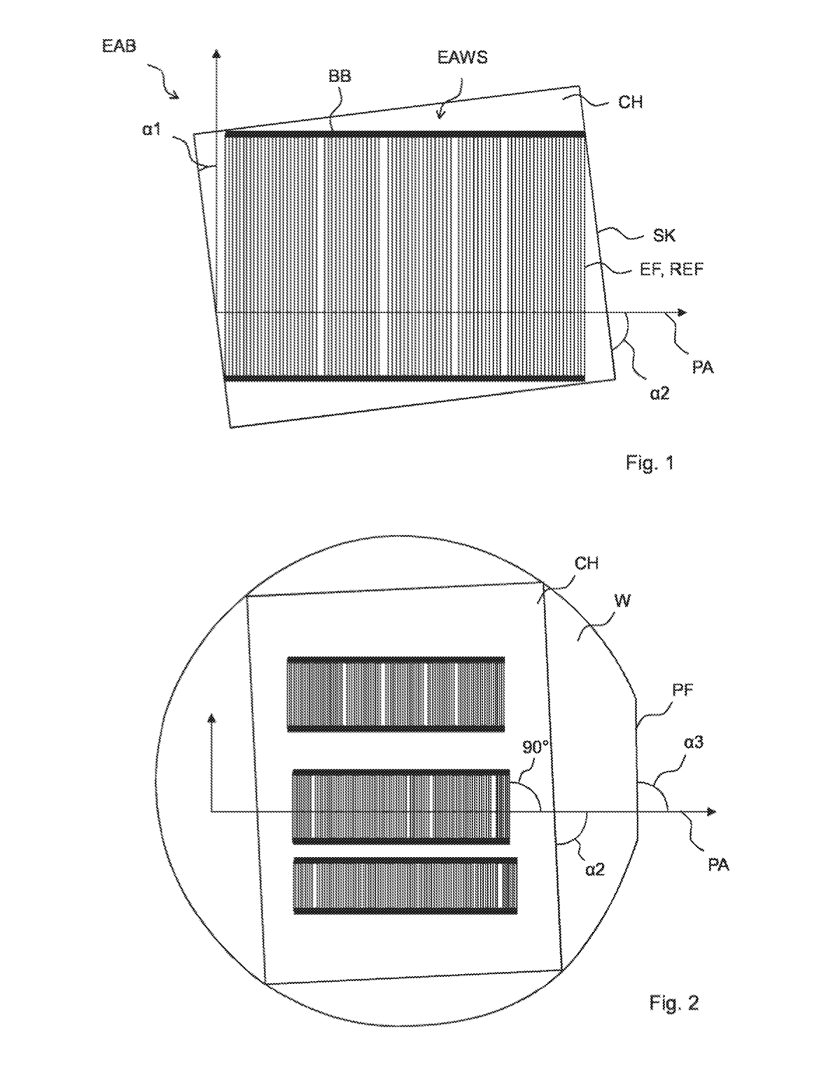

FIG. 1: the relative orientation between chip and transducer structures;

FIG. 2: the relative orientation of the piezoelectric axis, of the chip edges, and of the wafer in an embodiment;

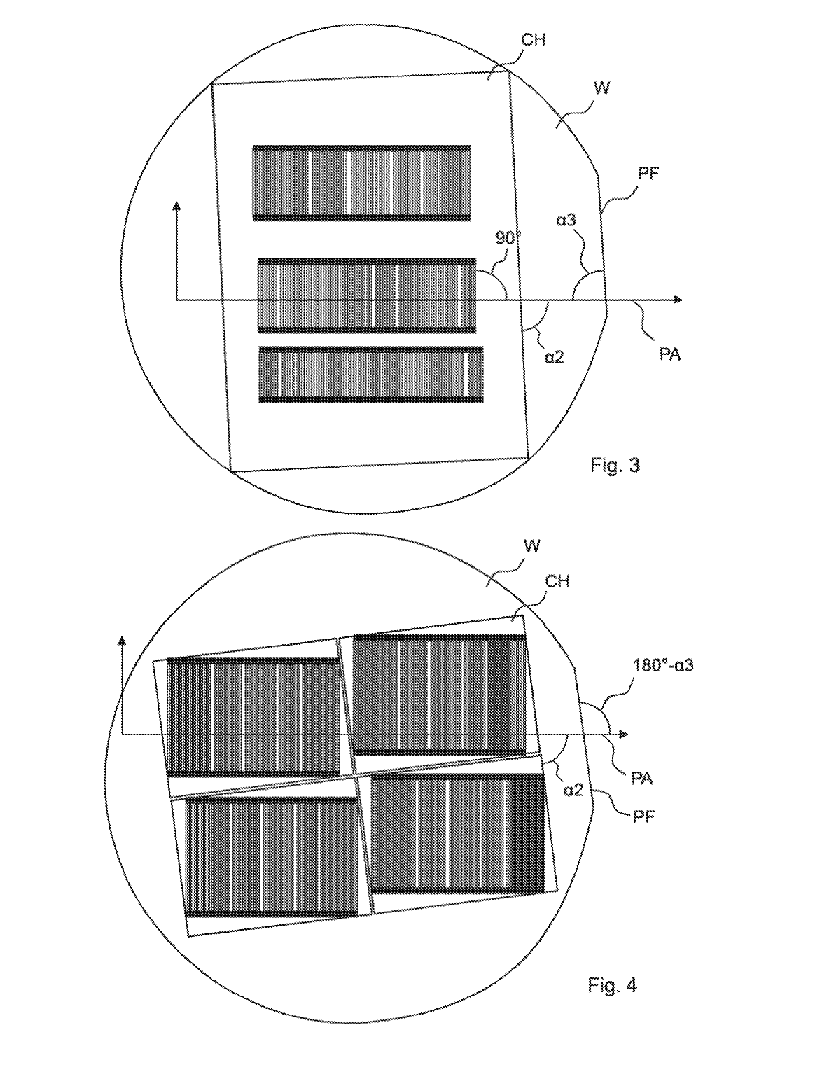

FIG. 3: the relative arrangement of the piezoelectric axis, of the chip edges, and of the marking of the wafer in an alternative embodiment;

FIG. 4: the arrangement of multiple, subsequent chips on a wafer;

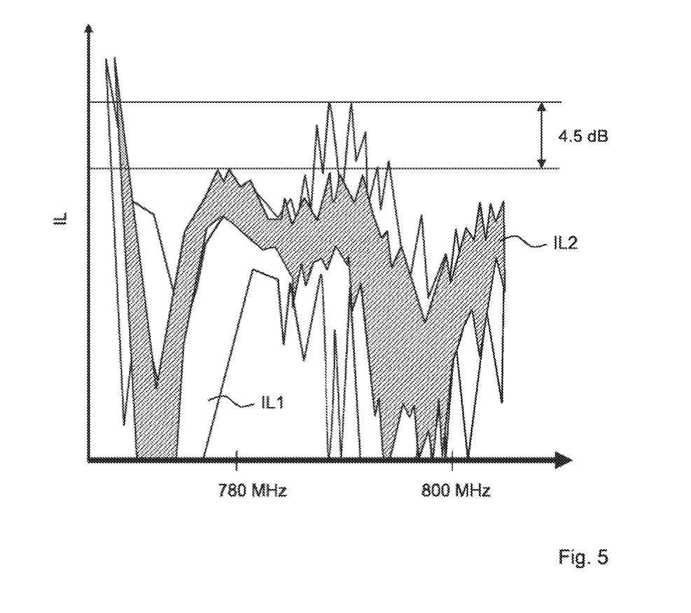

FIG. 5: the improvement of the insertion loss with electro-acoustic components of the aforementioned type;

FIG. 1 shows an electro-acoustic component EAB in which electro-acoustic transducer structures EAWS are arranged on a chip CH. The chip comprises a piezoelectric material with a piezoelectric axis PA. The chip CH has a rectangular footprint with four side edges SK. The transducer structures EAWS comprise busbars BB and a plurality of electrode fingers EF and reflector elements REF. The electrode fingers EF and the reflector elements REF are thereby arranged in the acoustic trace of the component EAB. The electrode fingers EF are thereby arranged at a right angle to the piezoelectric axis PA in order to enable optimal electro-acoustic coupling. The side edges SK of the chip CH are rotated at an angle α1 as compared to conventional components. The piezoelectric axis thus forms, with a side edge SK, an angle α2 which deviates from a right angle by α1. The surface area requirements of the chip CH are thereby increased as compared to conventional components because the surface of the piezoelectric chip cannot be used for transducer structures with a rectangular cross-section in the area of the four chip edges.

FIG. 2 shows how the chip, piezoelectric axis PA, and wafer W are oriented relative to one another. The electrode fingers on the chip are positioned vertically on the piezoelectric axis PA. A chip edge forms, with the piezoelectric axis, an angle α2 which deviates from a right angle. The chip CH is thereby cut from a wafer W by sawing. The orientation of the marking (primary flat) PF of the wafer forms the angle α3 with the piezoelectric axis PA. If α3 characterizes a right angle, then wafer W corresponds to a customary wafer.

FIG. 3 shows an advantageous wafer W in which the marking PF is rotated relative to the piezoelectric axis PA, analogous to the side edge of the chip. The marking PF and the piezoelectric axis PA form an angle α3, equal to the angle α2 that the chip edge and the piezoelectric axis PA enclose. Angles α2 and α3 in this case deviate from a right angle by the angle that is preferably between 3° and 10°. The transducer structures can thereby be oriented orthogonal to the piezoelectric axis and obtain a good electro-acoustic coupling. Simultaneously, a production method is simplified because the cut edges of the subsequent chips are oriented parallel or orthogonal to the marking PF of the transducer.

FIG. 4 shows how a plurality of subsequent chips (for example here four) can be arranged relative to one another and relative to the marking PF of the wafer W. The individual chips CH with the transducer structures thereupon are obtained by sawing of the wafer W.

FIG. 5 shows the progression of a plurality of individual, actually implemented measurements of the insertion loss (IL) for a plurality of conventional components IL1 and for a plurality of similar improved components IL2 in which rectangular transducer structures are arranged on rectangular chips, the electrode fingers of the transducer structures are oriented at a right angle with respect to the piezoelectric axis, and the substrate edges of the chip are rotated by a few degrees as compared to the piezoelectric axis. The components thereby realize bandpass filters with a DMS structure and at least one basic element of a ladder-type structure. The bandpass filter itself has a passband range between 734 MHz and 756 MHz. The insertion loss at 790 MHz is improved by 4.5 dB, on average.

The component is thereby not limited to the embodiments described. Components comprising additional component structures, such as additional electrode fingers or reflector elements, also represent embodiments according to the invention.

### LIST OF REFERENCE SIGNS

BB: busbar
CH: chip
EAB: electro-acoustic component
EAWS: electro-acoustic transducer structure
EF: electrode finger
IL1: insertion loss of conventional component
IL2: insertion loss of components in which the rectangular chip is rotated relative to the piezoelectric axis
PA: piezoelectric axis
PF: marking of the wafer
REF: reflector elements
SK: side edge of chip
α1: angle by which the substrate edges are rotated relative to conventional components or angle between the electrode fingers and a side edge
α2: angle between the substrate edge SK and the piezoelectric axis PA
α3: angle between the marking of the wafer and the piezoelectric axis

1. An electro-acoustic component (EAB), comprising
a carrier chip (CH) having a piezoelectric material with a piezoelectric axis (PA),
AW transducer structures (EAWS) having electrode fingers (EF) which are arranged on the carrier chip (CH),
wherein
the electrode fingers (EF) are oriented at a right angle with respect to the piezoelectric axis (PA) and
the piezoelectric axis (PA) does not intersect at a right angle with any of the substrate edges (SK).

2. The electro-acoustic component according to the previous claim, wherein the carrier chip (CH) has a rectangular cross-section.

3. The electro-acoustic component according to the previous claim, wherein the piezoelectric axis (PA) and a substrate edge (SK) form an angle α2 which is within an interval [80°, . . . , 87°].

4. The electro-acoustic component according to any of the previous claims, wherein the piezoelectric material is a monocrystal.

5. The electro-acoustic component according to any of the previous claims, wherein the piezoelectric material is LiTaO₃ or LiNbO₃.

6. The electro-acoustic component according to any of the previous claims, wherein the transducer structures (EAWS) have two busbars (BB) which are oriented at a right angle to the electrode fingers (EF).

7. The electro-acoustic component according to any of the previous claims, wherein the transducer structures (EAWS) comprise DMS structures.

8. The electro-acoustic component according to any of the previous claims, wherein the transducer structures (EAWS) comprise ladder-type structures.

9. HF filter with an electro-acoustic component according to any of the previous claims.

10. A wafer (W), comprising
a piezoelectric material with a piezoelectric axis (PA),
a first marking (PF) which is provided to indicate the orientation of the wafer (W),
wherein
the marking (PF) comprises an edge section progressing in a straight line, and
the piezoelectric axis (PA) intersects the edge section at an angle α3 that deviates from a right angle.

11. The wafer according to the previous claim, wherein the deviation |α3−90| is within an interval [3°, . . . , 10°].

12. A method for producing a plurality of electro-acoustic components (EAB) according to any of claims 1 to 9, comprising the steps:
Provision of a wafer (W) according to the previous claim;
Formation of the transducer structures (EAWS) of the components (EAB) on the wafer;
Separation of the components (EAB) by separating the wafer (W) into chips (CH) in which the edges (SK) are oriented parallel or at a right angle to the marking (PF) of the wafer (W).

13. A method for producing a plurality of electro-acoustic components according to any of claims 1 to 9, comprising the steps:
Provision of a wafer (W);
Formation of the transducer structures (EAWS) of the components (EAB) on the wafer;
Separation of the components (EAB) by separating the wafer (W) in chips (CH).

14. The method according to the previous claim, wherein the wafer (W) is sawed during separation.

15. The method according to either of the two previous claims, in which the transducer structures (EAB) are rotated by an angle α1 within an interval [3°, . . . , 10°] relative to the right-angled orientation of the subsequent chip edges (SK).
